(19) United States
(12) Patent Application Publication
(10) Pub. No.: US 2016/0343779 A1
(43) Pub. Date: Nov. 24, 2016

(54) WOLED DISPLAY DEVICE AND MANUFACTURE METHOD THEREOF

(71) Applicant: SHENZHEN CHINA STAR OPTOELECTRONICS TECHNOLOGY CO. LTD., Guangdong (CN)

(72) Inventors: Hejing ZHANG, Shenzhen, Guangdong (CN); Yawei LIU, Shenzhen, Guangdong (CN)

(73) Assignee: Shenzhen China Star Optoelectronics Technology Co. Ltd., Shenzhen, Guangdong (CN)

(21) Appl. No.: 14/429,356

(22) PCT Filed: Feb. 9, 2015
(86) PCT No.: PCT/CN2015/072547

§ 371 Date: Mar. 18, 2015

(30) Foreign Application Priority Data
Dec. 18, 2014 (CN) 201410795210.4

(51) Int. Cl. H01L 27/32; H01L 51/56; H01L 51/52

(52) U.S. Cl. CPC H01L 27/3213; H01L 27/3262; H01L 27/3258; H01L 27/3276; H01L 51/5206; H01L 51/5221; H01L 51/56; H01L 27/322; H01L 27/1248

(57) ABSTRACT

The present invention provides a WOLED display device and a manufacture method thereof. By locating a thickness of a part of the insulative layers correspondingly positioned above the bottom layer wiring in the white sub pixel area is larger than a thickness of other part of the insulative layers in the white sub pixel area to increase a vertical distance from the first electrode to the bottom layer wiring in the white sub pixel area, and meanwhile, by locating the first electrode and the bottom layer wiring in the white sub pixel area to be spaced with a distance in the horizontal direction to make a larger space between the first electrode and the bottom layer wiring, and thus, the bad phenomenon of the short circuit, the overcurrent caused by impurity substance between the first electrode and the bottom layer wiring can be avoided. The manufacture method of the WOLED display device is simple, easy for operation, and can prevent the short circuit or the overcurrent between the first electrode and the bottom layer wiring in the white sub pixel area occur and raise the manufacture yield of the WOLED display device.

### FIELD OF THE INVENTION

The present invention relates to a display technology field, and more particularly to a WOLED display device and a manufacture method thereof.

### BACKGROUND OF THE INVENTION

Active Matrix/Organic Light Emitting Diode (AMOLED) possesses properties of fast response, high contrast, wide view angle, etc. and is considered to be the next generation display technology. With the popularity of the high resolution and large scale panels, the difficulty of the process for the parallel arrangement AMOLED and the lifetime problem of the luminescent material are highlighted. These can easily cause the color impurity and the brightness deterioration of the panel. Thus, in the industry, the white organic light emitting diode (WOLED) plus the color filter are employed to solve the aforesaid problems.

The WOLED utilizes the red, the green, the blue filters to realize the red sub pixel, the green sub pixel and the blue sub pixel. Thus, the pixel without the color filter becomes a white sub pixel. However, some issues remain for the present WOLED display devices.

FIG. 1 is a structural diagram of a WOLED display device according to prior art. The first electrode of the WOLED is divided into the first electrode 910 in the white sub pixel area of the WOLED display device, and the first electrode 920 in the red/green/blue sub pixel areas of the WOLED display device. The white sub pixel does not comprise any color filter. Therefore, the layer where the white sub pixel of the WOLED is formed is lower than the layer where the red/green/blue sub pixels are formed. In such condition, as a result, the vertical distance d1 between the bottom layer wiring 521 and the first electrode 910 of the WOLED is shorter, and the vertical distance d2 between the first electrode 920 corresponded with the red/green/blue sub pixels and the bottom layer wiring 521 is longer. The white sub pixel and the red/green/blue sub pixels form the step difference d2−d1. In practical manufacture process of the WOLED panels, the existence of impurity substance 200 (such as photo residual glue, etching residual glue, external pollutant, etc.) can cause the short circuit or overcurrent phenomenon between the bottom layer wiring 521 and the first electrode 910 of the OLED of the white sub pixel.

Therefore, there is a need to improve the structure of the present WOLED display device to solve the aforesaid issues.

### SUMMARY OF THE INVENTION

An objective of the present invention is to provide a WOLED display device, of which the first electrode and the bottom layer wiring of the white organic light emitting diode has a larger space to avoid the bad phenomenon of the short circuit, the overcurrent caused by impurity substance between the first electrode and the bottom layer wiring.

Another objective of the present invention is to provide a manufacture method of a WOLED display device, which is simple, easy for operation, and can prevent the short circuit or the overcurrent between the first electrode and the bottom layer wiring of the white sub pixel area occur and raise the manufacture yield of the WOLED display device.

For realizing the aforesaid objectives, the present invention provides a WOLED display device, comprising a red sub pixel area, a green sub pixel area, a blue sub pixel area and a white sub pixel area;

wherein the white sub pixel area comprises: a first substrate, a bottom layer wiring and a thin film transistor located on the first substrate, a second insulative layer located on the bottom layer wiring, the thin film transistor and the first substrate, a third insulative layer located on the second insulative layer, a first electrode located on the third insulative layer, an organic layer located on the first electrode, a second electrode located on the organic layer and a second substrate located on the second electrode;

a thickness of a part of the insulative layers correspondingly positioned above the bottom layer wiring in the white sub pixel area is larger than a thickness of other part of the insulative layers in the white sub pixel area.

A thickness of a part of the third insulative layer correspondingly positioned above the bottom layer wiring in the white sub pixel area is larger than a thickness of other part of the third insulative layer in the white sub pixel area.

The first electrode and the bottom layer wiring are spaced with a distance in the horizontal direction.

A thickness of a part of the second insulative layer correspondingly positioned above the bottom layer wiring in the white sub pixel area is larger than a thickness of other part of the second insulative layer in the white sub pixel area.

The first substrate is a transparent substrate; the first electrode is an anode, which is a transparent electrode; the second electrode is a cathode, which is a reflective electrode.

The present invention further provides a manufacture method of a WOLED display device, comprising steps of:

step 1, providing a first substrate, and manufacturing a thin film transistor and a bottom layer wiring on the first substrate, and forming a second insulative layer on the bottom layer wiring, the thin film transistor and the first substrate;

step 2, locating a red light filter on the second insulative layer in a red sub pixel area, and locating a green light filter on the second insulative layer in a green sub pixel area, and locating a blue light filter on the second insulative layer in a blue sub pixel area; then, forming a third insulative layer on the second insulative layer and the red light, the green light and the blue light filters;

step 3, sequentially forming a first electrode and an organic layer on the third insulative layers in the red sub pixel area, the green sub pixel area, the blue sub pixel area and the white sub pixel area, and meanwhile, forming a spacer layer on the third insulative layer between every two adjacent sub pixel areas; then, forming a second electrode on the organic layer and the spacer layer, and locating a second substrate on the second electrode.

In the step 1, a thickness of a part of the second insulative layer correspondingly positioned above the bottom layer wiring in the white sub pixel area is larger than a thickness of other part of the second insulative layer in the white sub pixel area.

In the step 2, a thickness of a part of the third insulative layer correspondingly positioned above the bottom layer wiring in the white sub pixel area is larger than a thickness of other part of the third insulative layer in the white sub pixel area.

The first electrode and the bottom layer wiring are spaced with a distance in the horizontal direction.

The first substrate is a transparent substrate; the first electrode is an anode, which is a transparent electrode; the second electrode is a cathode, which is a reflective electrode.

The present invention further provides a WOLED display device, comprising a red sub pixel area, a green sub pixel area, a blue sub pixel area and a white sub pixel area;

wherein the white sub pixel area comprises: a first substrate, a bottom layer wiring and a thin film transistor located on the first substrate, a second insulative layer located on the bottom layer wiring, the thin film transistor and the first substrate, a third insulative layer located on the second insulative layer, a first electrode located on the third insulative layer, an organic layer located on the first electrode, a second electrode located on the organic layer and a second substrate located on the second electrode;

a thickness of a part of the insulative layers correspondingly positioned above the bottom layer wiring in the white sub pixel area is larger than a thickness of other part of the insulative layers in the white sub pixel area;

wherein a thickness of a part of the third insulative layer correspondingly positioned above the bottom layer wiring in the white sub pixel area is larger than a thickness of other part of the third insulative layer in the white sub pixel area;

wherein the first substrate is a transparent substrate; the first electrode is an anode, which is a transparent electrode; the second electrode is a cathode, which is a reflective electrode.

The benefits of the present invention are: the present invention provides a WOLED display device, of which a thickness of a part of the insulative layers correspondingly positioned above the bottom layer wiring in the white sub pixel area is larger than a thickness of other part of the insulative layers in the white sub pixel area to make a larger vertical distance from the first electrode to the bottom layer wiring in the white sub pixel area, and meanwhile, the first electrode and the bottom layer wiring are spaced with a distance in the horizontal direction to make a larger space between the first electrode and the bottom layer wiring, and thus, the bad phenomenon of the short circuit, the overcurrent caused by impurity substance between the first electrode and the bottom layer wiring can be avoided. The quality of the WOLED display device is promoted. The present invention provides a manufacture method of a WOLED display device. By locating a thickness of a part of the insulative layers correspondingly positioned above the bottom layer wiring in the white sub pixel area is larger than a thickness of other part of the insulative layers in the white sub pixel area to increase a vertical distance from the first electrode to the bottom layer wiring in the white sub pixel area, and meanwhile, by locating the first electrode and the bottom layer wiring in the white sub pixel area to be spaced with a distance in the horizontal direction to make a larger space between the first electrode and the bottom layer wiring, and thus, the bad phenomenon of the short circuit, the overcurrent caused by impurity substance between the first electrode and the bottom layer wiring can be avoided. The manufacture process is simple, easy for operation, and can prevent the short circuit or the overcurrent between the first electrode and the bottom layer wiring in the white sub pixel area occur and raise the manufacture yield of the WOLED display device.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structural diagram of a WOLED display device according to prior art;

FIG. 2 is a structural diagram of a WOLED display device according to the first embodiment of the present invention;

FIG. 3 is a structural diagram of a WOLED display device according to the second embodiment of the present invention;

FIG. 4 is a flowchart of a manufacture method of the WOLED display device according to the present invention.

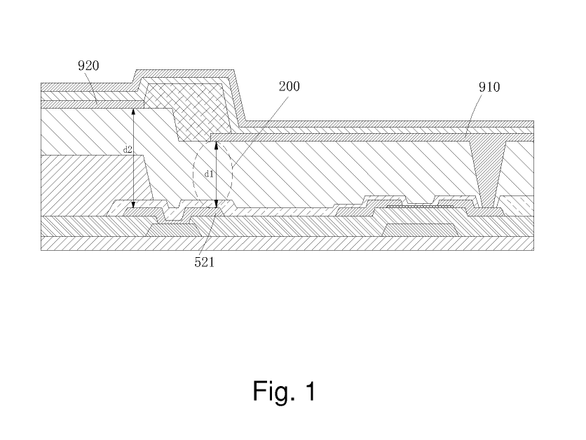

### DETAILED DESCRIPTION OF PREFERRED EMBODIMENTS

For better explaining the technical solution and the effect of the present invention, the present invention will be further described in detail with the accompanying drawings and the specific embodiments.

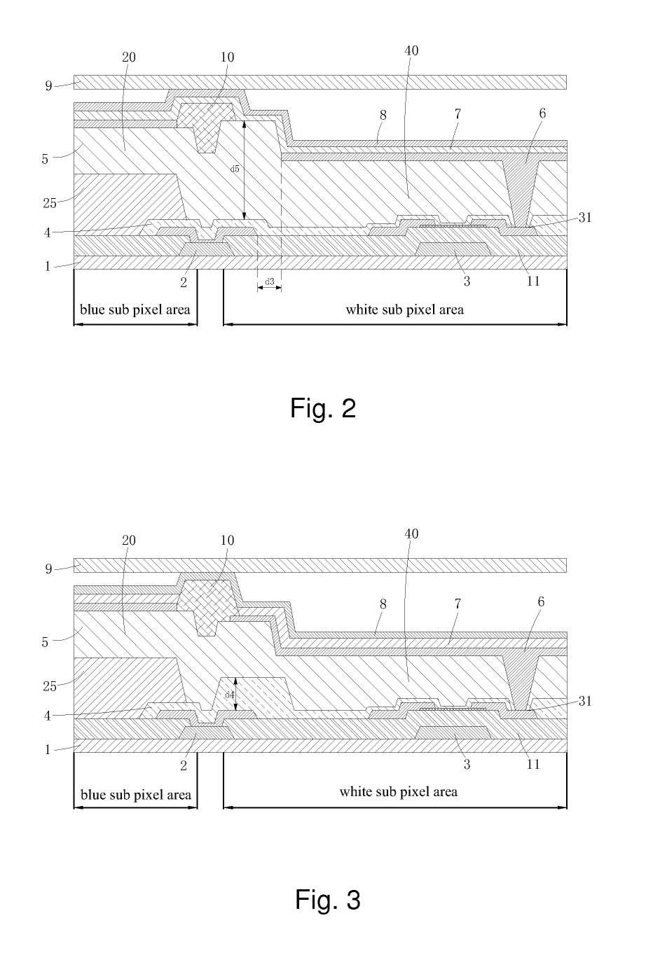

Please refer to FIG. 2, which is a structural diagram of a WOLED display device according to the first embodiment of the present invention. As shown in FIG. 2, the present invention provides a WOLED display device, comprising a red sub pixel area, a green sub pixel area, a blue sub pixel area 20 and a white sub pixel area 40.

The white sub pixel area 40 comprises a first substrate 1, a bottom layer wiring 2 and a thin film transistor 3 located on the first substrate 1, a second insulative layer 4 located on the bottom layer wiring 2, the thin film transistor 3 and the first substrate 1, a third insulative layer 5 located on the second insulative layer 4, a first electrode 6 located on the third insulative layer 5, an organic layer 7 located on the first electrode 6, a second electrode 8 located on the organic layer 7 and a second substrate 9 located on the second electrode 8;

the blue sub pixel area 20 comprises a first substrate 1, a bottom layer wiring 2 and a thin film transistor 3 located on the first substrate 1, a second insulative layer 4 located on the bottom layer wiring 2, the thin film transistor 3 and the first substrate 1, a blue light filter 25 located on the second insulative layer 4, a third insulative layer 5 located on the blue light filter 25, a first electrode 6 located on the third insulative layer 5, an organic layer 7 located on the first electrode 6, a second electrode 8 located on the organic layer 7 and a second substrate 9 located on the second electrode 8;

the red sub pixel area (not shown) comprises a first substrate 1, a bottom layer wiring 2 and a thin film transistor 3 located on the first substrate 1, a second insulative layer 4 located on the bottom layer wiring 2, the thin film transistor 3 and the first substrate 1, a red light filter located on the second insulative layer 4, a third insulative layer 5 located on the red light filter, a first electrode 6 located on the third insulative layer 5, an organic layer 7 located on the first electrode 6, a second electrode 8 located on the organic layer 7 and a second substrate 9 located on the second electrode 8;

the green sub pixel area (not shown) comprises a first substrate 1, a bottom layer wiring 2 and a thin film transistor 3 located on the first substrate 1, a second insulative layer 4 located on the bottom layer wiring 2, the thin film transistor 3 and the first substrate 1, a green light filter located on the second insulative layer 4, a third insulative layer 5 located on the green light filter, a first electrode 6 located on the third insulative layer 5, an organic layer 7 located on the first electrode 6, a second electrode 8 located on the organic layer 7 and a second substrate 9 located on the second electrode 8.

Wherein, a thickness d5 of a part of the third insulative layer 5 correspondingly positioned above the bottom layer wiring 2 in the white sub pixel area 40 is larger than a thickness of other part of the third insulative layer 5 in the white sub pixel area 40; the first electrode 6 and the bottom layer wiring 2 are spaced with a distance d3 in the horizontal direction.

By setting the third insulative layer 8 between the first electrode 6 and the bottom layer wiring 2 to have the larger thickness d5, and spacing the first electrode 6 and the bottom layer wiring 2 with the distance d3 in the horizontal direction, the space between the first electrode 6 and the bottom layer wiring 2 is enlarged, which can effectively avoid the defects of the short circuit, the overcurrent caused by impurity substance between the first electrode 6 and the bottom layer wiring 2.

A spacer layer 10 is formed between any two adjacent sub pixel areas in the red sub pixel area, the green sub pixel area, the blue sub pixel area 20 and the white sub pixel area 40. The spacer layer 10 is between the third insulative layer 5 and the second electrode 8, and separates the first electrode 6 and the organic layer 7 in two adjacent sub pixel areas. The spacer layer 10 does not only separate the adjacent sub pixel areas but also support the second substrate 9. Preferably, the spacer layer 10 is manufactured with insulative material.

Specifically, the bottom layer wiring 2 comprises signal lines, such as data line DL1-DLn and SL1-SLm and power lines, such as high voltage level power lines EVDD and low voltage level power lines EVSS. If the sub pixel comprises a compensation circuit, the bottom layer wiring may further comprise auxiliary power line for providing auxiliary voltages, reference power lines for providing reference voltages, and initialization power lines for providing initialization voltages.

Specifically, the first substrate 1 is a transparent substrate, and the first electrode 6 is an anode, which is a transparent electrode manufactured with transparent conductive material, such as ITO (Indium-Tin-Oxide); the second electrode 8 is a cathode, which is a reflective electrode manufactured by metal material, such as aluminum, magnesium or silver.

The organic light emitting layer 7 emits white light. Specifically, the organic layer 7 comprises: a Hole Transport Layer located on the first electrode 6, an white light emitting layer located on the Hole Transport Layer, an Electron Transport Layer located on the white light emitting layer; as a certain driving voltage is applied between the first electrode 6 and the second electrode 8, the Electron and the Hole are respectively injected into the Electron Transport Layer and Hole Transport Layer from the second electrode 8 and the first electrode 6, and the Electron and the Hole respectively migrate from the Electron Transport Layer and Hole Transport Layer to the emitting layer and bump into each other in the white light emitting layer to form an exciton to excite the emitting molecule. The latter can illuminate after the radiative relaxation. The light directly goes out by passing through the transparent first electrode 6 or goes out by passing through the transparent first electrode 6 after being reflected by the reflective second electrode 8.

Specifically, the thin film transistor 3 comprises a gate layer located on the first substrate 1, a first insulative layer 11 located on the gate layer, a semiconductor layer located on the first insulative layer 11 and a source/a drain layer located on the semiconductor layer. The first electrode 6 is electrically connected to the drain of the thin film transistor 3 through a via hole 31 penetrating the second insulative layer 4 and the third insulative layer 5.

Please refer to FIG. 3, which is a structural diagram of a WOLED display device according to the second embodiment of the present invention. As shown in FIG. 3, the present invention provides a WOLED display device, comprising a red sub pixel area, a green sub pixel area, a blue sub pixel area 20 and a white sub pixel area 40.

The white sub pixel area 40 comprises a first substrate 1, a bottom layer wiring 2 and a thin film transistor 3 located on the first substrate 1, a second insulative layer 4 located on the bottom layer wiring 2, the thin film transistor 3 and the first substrate 1, a third insulative layer 5 located on the second insulative layer 4, a first electrode 6 located on the third insulative layer 5, an organic layer 7 located on the first electrode 6, a second electrode 8 located on the organic layer 7 and a second substrate 9 located on the second electrode 8;

wherein a thickness d4 of a part of the second insulative layer 4 correspondingly positioned above the bottom layer wiring 2 in the white sub pixel area 40 is larger than a thickness of other part of the second insulative layer 4 in the white sub pixel area 40.

By setting the second insulative layer 6 between the first electrode 6 and the bottom layer wiring 2 to have the larger thickness d4, the space between the first electrode 6 and the bottom layer wiring 2 is enlarged, which can effectively avoid the defects of the short circuit, the overcurrent caused by impurity substance between the first electrode 6 and the bottom layer wiring 2.

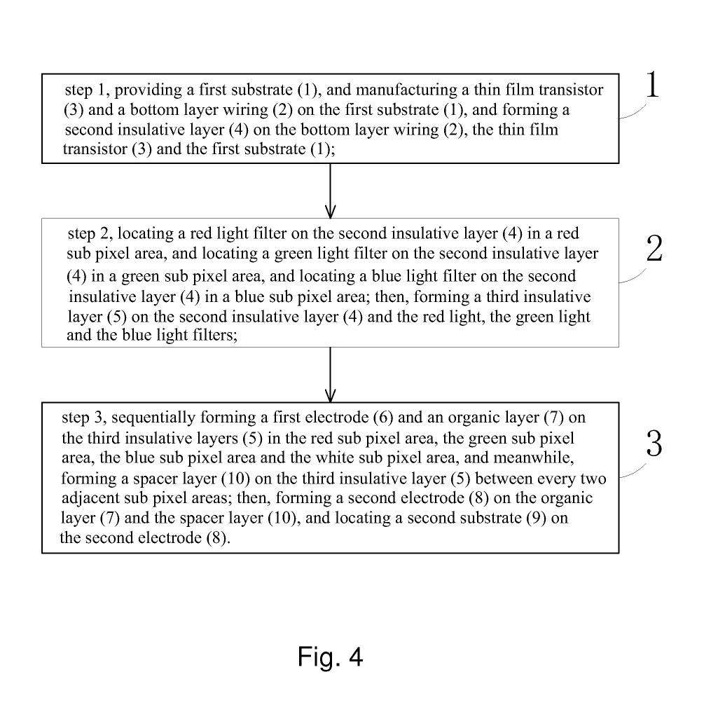

Please refer to FIG. 4. The present invention further provides a manufacture method of the WOLED display device of the aforementioned first embodiment, comprising steps of:

step 1, providing a first substrate 1, and manufacturing a thin film transistor 3 and a bottom layer wiring 2 on the first substrate 1, and forming a second insulative layer 4 on the bottom layer wiring 2, the thin film transistor 3 and the first substrate 1.

The bottom layer wiring 2 comprises signal lines, such as data line DL1-DLn and SL1-SLm and power lines, such as high voltage level power lines EVDD and low voltage level power lines EVSS. If the sub pixel comprises a compensation circuit, the bottom layer wiring may further comprise auxiliary power line for providing auxiliary voltages, reference power lines for providing reference voltages, and initialization power lines for providing initialization voltages.

Specifically, the manufacture steps of the thin film transistor 3 is: sequentially deposing a gate layer, a first insulative layer 11 located on the gate layer, a semiconductor layer located on the first insulative layer 11 and a source/a drain layer located on the semiconductor layer on the first substrate 1.

Step 2, locating a red light filter on the second insulative layer 4 in a red sub pixel area, and locating a green light filter on the second insulative layer 4 in a green sub pixel area, and locating a blue light filter on the second insulative layer 4 in a blue sub pixel area; then, forming a third insulative layer 5 on the second insulative layer 4 and the red light, the green light and the blue light filters.

Wherein a thickness d5 of a part of the third insulative layer 5 correspondingly positioned above the bottom layer wiring 2 in the white sub pixel area 40 is larger than a thickness of other part of the third insulative layer 5 in the white sub pixel area 40.

Step 3, sequentially forming a first electrode 6 and an organic layer 7 on the third insulative layers 5 in the white sub pixel area 40, the red sub pixel area, the green sub pixel area and the blue sub pixel area 20, and meanwhile, forming a spacer layer 10 on the third insulative layer 5 between every two adjacent sub pixel areas; then, forming a second electrode 8 on the organic layer 7 and the spacer layer 10, and locating a second substrate 9 on the second electrode 8.

Wherein, the first electrode 6 and the bottom layer wiring 2 are spaced with a distance d3 in the horizontal direction.

Wherein, the spacer layer 10 does not only separate the adjacent sub pixel areas but also support the second substrate 9. The spacer layer 10 is constructed with insulative material.

The step 3 further comprises a step of: forming a via hole 31 in the second insulative layer 4 and the third insulative layer 5, and the first electrode 6 is electrically connected to the drain of the thin film transistor 3 through the via hole 31 penetrating the second insulative layer 4 and the third insulative layer 5.

The aforesaid manufacture method of the WOLED display device sets the third insulative layer 8 between the first electrode 6 and the bottom layer wiring 2 to have the larger thickness d5, and spaces the first electrode 6 and the bottom layer wiring 2 with the distance d3 in the horizontal direction. Thus, the space between the first electrode 6 and the bottom layer wiring 2 is enlarged, which can effectively avoid the defects of the short circuit, the overcurrent caused by impurity substance between the first electrode 6 and the bottom layer wiring 2.

Please refer to FIG. 4. The present invention further provides a manufacture method of the WOLED display device of the aforementioned second embodiment, comprising steps of:

step 1, providing a first substrate 1, and manufacturing a thin film transistor 3 and a bottom layer wiring 2 on the first substrate 1, and forming a second insulative layer 4 on the bottom layer wiring 2, the thin film transistor 3 and the first substrate 1.

Wherein, a thickness of a part of the second insulative layer 4 correspondingly positioned above the bottom layer wiring 2 in the white sub pixel area 40 is larger than a thickness of other part of the second insulative layer 4 in the white sub pixel area 40.

Step 2, locating a red light filter on the second insulative layer 4 in a red sub pixel area, and locating a green light filter on the second insulative layer 4 in a green sub pixel area, and locating a blue light filter on the second insulative layer 4 in a blue sub pixel area; then, forming a third insulative layer 5 on the second insulative layer 4 and the red light, the green light and the blue light filters.

Step 3, sequentially forming a first electrode 6 and an organic layer 7 on the third insulative layers 5 in the white sub pixel area 40, the red sub pixel area, the green sub pixel area and the blue sub pixel area 20, and meanwhile, forming a spacer layer 10 on the third insulative layer 5 between every two adjacent sub pixel areas; then, forming a second electrode 8 on the organic layer 7 and the spacer layer 10, and locating a second substrate 9 on the second electrode 8.

The aforesaid manufacture method of the WOLED display device sets the second insulative layer 6 between the first electrode 6 and the bottom layer wiring 2 to have the larger thickness d4. Thus, the space between the first electrode 6 and the bottom layer wiring 2 is enlarged, which can effectively avoid the defects of the short circuit, the overcurrent caused by impurity substance between the first electrode 6 and the bottom layer wiring 2.

In conclusion, the present invention provides a WOLED display device, of which a thickness of a part of the insulative layers correspondingly positioned above the bottom layer wiring in the white sub pixel area is larger than a thickness of other part of the insulative layers in the white sub pixel area to make a larger vertical distance from the first electrode to the bottom layer wiring in the white sub pixel area, and meanwhile, the first electrode and the bottom layer wiring are spaced with a distance in the horizontal direction to make a larger space between the first electrode and the bottom layer wiring, and thus, the bad phenomenon of the short circuit, the overcurrent caused by impurity substance between the first electrode and the bottom layer wiring can be avoided. The quality of the WOLED display device is promoted. The present invention provides a manufacture method of a WOLED display device. By locating a thickness of a part of the insulative layers correspondingly positioned above the bottom layer wiring in the white sub pixel area is larger than a thickness of other part of the insulative layers in the white sub pixel area to increase a vertical distance from the first electrode to the bottom layer wiring in the white sub pixel area, and meanwhile, by locating the first electrode and the bottom layer wiring in the white sub pixel area to be spaced with a distance in the horizontal direction to make a larger space between the first electrode and the bottom layer wiring, and thus, the bad phenomenon of the short circuit, the overcurrent caused by impurity substance between the first electrode and the bottom layer wiring can be avoided. The manufacture process is simple, easy for operation, and can prevent the short circuit or the overcurrent between the first electrode and the bottom layer wiring in the white sub pixel area occur and raise the manufacture yield of the WOLED display device.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A WOLED display device, comprising a red sub pixel area, a green sub pixel area, a blue sub pixel area and a white sub pixel area;
wherein the white sub pixel area comprises: a first substrate, a bottom layer wiring and a thin film transistor located on the first substrate, a second insulative layer located on the bottom layer wiring, the thin film transistor and the first substrate, a third insulative layer located on the second insulative layer, a first electrode located on the third insulative layer, an organic layer located on the first electrode, a second electrode located on the organic layer and a second substrate located on the second electrode;
a thickness of a part of the insulative layers correspondingly positioned above the bottom layer wiring in the white sub pixel area is larger than a thickness of other part of the insulative layers in the white sub pixel area.

2. The WOLED display device according to claim 1, wherein a thickness of a part of the third insulative layer correspondingly positioned above the bottom layer wiring in the white sub pixel area is larger than a thickness of other part of the third insulative layer in the white sub pixel area.

3. The WOLED display device according to claim 2, wherein the first electrode and the bottom layer wiring are spaced with a distance in the horizontal direction.

4. The WOLED display device according to claim 1, wherein a thickness of a part of the second insulative layer correspondingly positioned above the bottom layer wiring in the white sub pixel area is larger than a thickness of other part of the second insulative layer in the white sub pixel area.

5. The WOLED display device according to claim 1, wherein the first substrate is a transparent substrate; the first electrode is an anode, which is a transparent electrode; the second electrode is a cathode, which is a reflective electrode.

6. A manufacture method of a WOLED display device, comprising steps of:
step 1, providing a first substrate, and manufacturing a thin film transistor and a bottom layer wiring on the first substrate, and forming a second insulative layer on the bottom layer wiring, the thin film transistor and the first substrate;
step 2, locating a red light filter on the second insulative layer in a red sub pixel area, and locating a green light filter on the second insulative layer in a green sub pixel area, and locating a blue light filter on the second insulative layer in a blue sub pixel area; then, forming a third insulative layer on the second insulative layer and the red light, the green light and the blue light filters;
step 3, sequentially forming a first electrode and an organic layer on the third insulative layers in the red sub pixel area, the green sub pixel area, the blue sub pixel area and the white sub pixel area, and meanwhile, forming a spacer layer on the third insulative layer between every two adjacent sub pixel areas; then, forming a second electrode on the organic layer and the spacer layer, and locating a second substrate on the second electrode.

7. The manufacture method of the WOLED display device according to claim 6, wherein in the step 1, a thickness of a part of the second insulative layer correspondingly positioned above the bottom layer wiring in the white sub pixel area is larger than a thickness of other part of the second insulative layer in the white sub pixel area.

8. The manufacture method of the WOLED display device according to claim 6, wherein in the step 2, a thickness of a part of the third insulative layer correspondingly positioned above the bottom layer wiring in the white sub pixel area is larger than a thickness of other part of the third insulative layer in the white sub pixel area.

9. The manufacture method of the WOLED display device according to claim 8, wherein the first electrode and the bottom layer wiring are spaced with a distance in the horizontal direction.

10. The manufacture method of the WOLED display device according to claim 6, wherein the first substrate is a transparent substrate; the first electrode is an anode, which is a transparent electrode; the second electrode is a cathode, which is a reflective electrode.

11. A WOLED display device, comprising a red sub pixel area, a green sub pixel area, a blue sub pixel area and a white sub pixel area;
wherein the white sub pixel area comprises: a first substrate, a bottom layer wiring and a thin film transistor located on the first substrate, a second insulative layer located on the bottom layer wiring, the thin film transistor and the first substrate, a third insulative layer located on the second insulative layer, a first electrode located on the third insulative layer, an organic layer located on the first electrode, a second electrode located on the organic layer and a second substrate located on the second electrode;
a thickness of a part of the insulative layers correspondingly positioned above the bottom layer wiring in the white sub pixel area is larger than a thickness of other part of the insulative layers in the white sub pixel area;
wherein a thickness of a part of the third insulative layer correspondingly positioned above the bottom layer wiring in the white sub pixel area is larger than a thickness of other part of the third insulative layer in the white sub pixel area;
wherein the first substrate is a transparent substrate; the first electrode is an anode, which is a transparent electrode; the second electrode is a cathode, which is a reflective electrode.

12. The WOLED display device according to claim 11, wherein the first electrode and the bottom layer wiring are spaced with a distance in the horizontal direction.
